(19) United States
(12) Patent Application Publication
(10) Pub. No.: US 2025/0372592 A1
(43) Pub. Date: Dec. 4, 2025

(54) APPARATUS WITH MULTI-INTERFACE TEST MECHANISM AND METHODS FOR OPERATING THE SAME

(71) Applicant: Micron Technology, Inc., Boise, ID (US)

(72) Inventors: Bokuba Nwengela, El Dorado Hills, CA (US); Raymond Chang, Sacramento, CA (US); Raghukiran Sreeramaneni, Frisco, TX (US); Nevil N. Gajera, Meridian, ID (US)

(21) Appl. No.: 19/212,686

(22) Filed: May 20, 2025

Related U.S. Application Data
(60) Provisional application No. 63/655,411, filed on Jun. 3, 2024.

(51) Int. Cl. H01L 25/18; G01R 31/28; H01L 23/00; H01L 23/538; H10B 80/00; H10D 80/30

(52) U.S. Cl. CPC H01L 25/18; G01R 31/2884; H01L 23/5385; H10B 80/00; H10D 80/30; H01L 24/16; H01L 2224/16235; H01L 2225/06517; H01L 2225/06541; H01L 2225/06596; H01L 2924/1431; H01L 2924/1432; H01L 2924/1436; H01L 2924/1437

(57) ABSTRACT

Methods, apparatuses, and systems related to adjustment of circuit tests are described. A memory device may include a self-test circuit that is configured to selectively suspend collection and/or processing of test results for one or more portions of the self-test.

### CROSS-REFERENCE TO RELATED APPLICATION(S)

The present application claims priority to U.S. Provisional Patent Application No. 63/655,411, filed Jun. 3, 2024, the disclosure of which is incorporated herein by reference in its entirety.

### TECHNICAL FIELD

The disclosed embodiments relate to devices, and, in particular, to semiconductor memory devices with a multi-interface test mechanism and methods for operating the same.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, increasing functionalities, reducing power consumption, or reducing manufacturing costs, among other metrics.

### BRIEF DESCRIPTION OF THE DRAWINGS

FIG. 1 a cross-sectional view of a system-in-package device in accordance with embodiments of the technology.

FIG. 2 is a schematic block diagram of a dedicated test circuit for a memory device.

FIG. 3 is a schematic block diagram of a memory device including a test circuit in accordance with an embodiment of the present technology.

FIG. 4A is a flow diagram illustrating an example method of manufacturing an apparatus in accordance with an embodiment of the present technology.

FIG. 4B is a flow diagram illustrating an example method of operating an apparatus in accordance with an embodiment of the present technology.

FIG. 5 is a schematic view of a system that includes an apparatus in accordance with an embodiment of the present technology.

### DETAILED DESCRIPTION

As described in greater detail below, the technology disclosed herein relates to an apparatus, such as for memory systems, systems with memory devices, related methods, etc., for providing multi-interface diagnostics mechanisms (e.g., self-tests). The apparatus can include a test circuit and an interface manager that are configured to selectively provide diagnostics features to two or more communicative or operative interfaces. For example, the test circuit and the interface manager can be configured to support multiple memory types, such as Static Random-Access Memory (SRAM), Dynamic Random-Access memory (DRAM), NAND or other type of persistent memory, on-die memory, off-die memory, and/or the like, from the same test circuit (e.g., a memory built-in self-test (mBIST) circuit). A user of the corresponding apparatus can customize the test circuit and the interface manager according to the intended application/deployment (e.g., the memory targeted for self-test).

In some embodiments, the test circuit and the interface manager can be implemented within an interface die, which can be used as a base die in a High-Bandwidth Memory (HBM) device. The test circuit and the interface manager can be configured to test different memory types and/or different communication interfaces (e.g., P1500, JTAG, ONFI, etc.). For the multi-interface support, the test circuit manager can include circuitry, software, firmware, or a combination thereof configured to drive and monitor multiple memory test patterns. The interface manager can circuitry, software, firmware, or a combination thereof configured to drive test signals according to the communication interface associated with the targeted memory type. Moreover, the interface manager can be configured to generate or convert test communications between the communication endpoints (e.g., a communication pad/port, such as for P1500 pad, a direct access pad, and/or the like, and the test circuit) according to corresponding interface protocol. Accordingly, the test circuit and the interface manager can support/implement self-tests of DRAM core dies within HBM, other memory (e.g., SRAM, NAND, other DRAM) within the HBM, off-chip memory external to the HBM, or a combination thereof.

Accordingly, the test circuit and the interface manager can provide increased customization for the corresponding memory device (e.g., the HBM). The customization can further allow the memory device to support memory expansions while enabling testability of each memory type using a single/common test circuit. In using the single test circuit to support tests of multiple memory types, the test circuit and the interface manager can eliminate separately targeted MBIST circuits, thereby reducing the footprint within the base die. Further, the test circuit and the interface manager can allow the test signals for the different memory types to travel through a common/shared path, thereby providing simpler signal routing and reduction in the external test communication points/pads.

### Example Environment

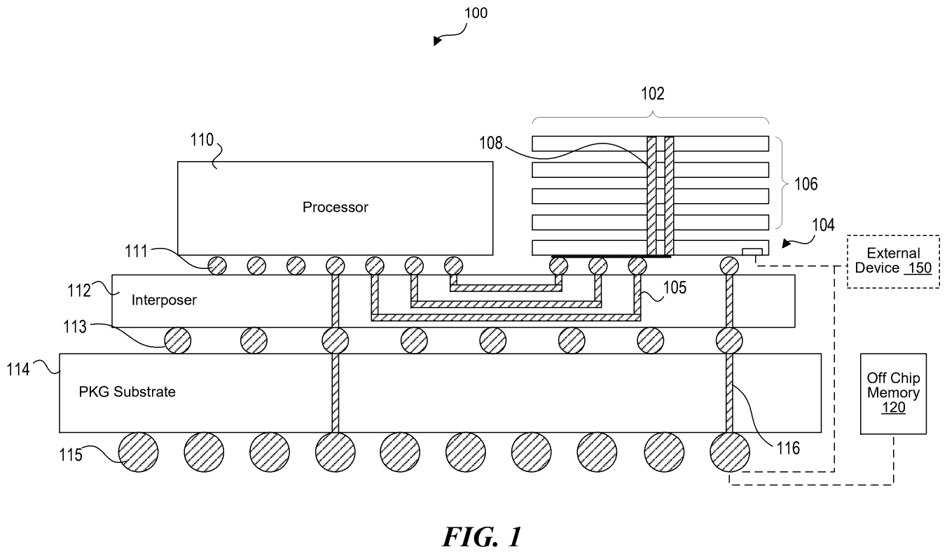

FIG. 1 illustrates a schematic cross-sectional view of a system-in-package (SiP) device 100 (i.e., an example apparatus) in accordance with embodiments of the technology. The SiP 100 can include a memory device 102 and a processor 110 (e.g., a central processing unit (CPU), a graphics processing unit (GPU), or the like), which are packaged together on a package substrate 114 along with an interposer 112. The processor 110 may act as a host device of the SiP 100.

In some embodiments, the memory device 102 may be a high-bandwidth memory (HBM) device that includes an interface die (or logic die) 104 and one or more memory core dies 106 stacked on the interface die 104. The memory core dies 106 can include DRAM devices/dies, NAND devices/dies, and/or other types of memory devices (e.g., static RAM (SRAM)) as main memory configured to store data provided by the processor 110 and to provide access of the stored data to the processor 110. The memory device 102 can further include additional and/or supplementary memory circuits (e.g., SRAM, DRAM, NAND, etc.), located within and/or outside of the core dies 106, configured for internal uses (e.g., remaining inaccessible to the processor 110). The memory device 102 can include one or more through silicon vias (TSVs) 108, which may be used to couple the interface die 104 and the core dies 106.

The interposer 112 (e.g., a silicon interposer) can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. While three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate may further include direct access (DA) bumps coupled through the package substrate 114 and interposer 112 to the interface die 104.

The memory device 102 can include memory in addition to the core dies 106 and/or the targeted memory cells therein. For example, the memory device 102 can include SRAM, persistent memory (e.g., NAND), hybrid memory devices, and/or the like in the interface die 104 and/or (in addition to the targeted memory cells, such as DRAM) in the core dies 106. In some embodiments, the core dies 106 can include multiple different types of memories or hybrid devices as the targeted memory cells. For example, the core dies 106 can include DRAM dies and NAND dies stacked on/over each other.

The memory device 102 can be further coupled to an off-chip memory 120. For example, the SiP device 100 can be implemented in a larger computing device, such as a mainframe computer, a server, a cloud computing device, a personal computing device, a wearable computer, a portable computing device, and/or the like. Moreover, the larger computing device can include the off-chip memory 120 that is physically separate from the memory device 102 and/or physically separate from the SiP device 100. The off-chip memory 120 can include SRAM, DRAM, and/or NAND devices attached to the interposer 112, the package substrate 114, or a different structure. The off-chip memory 120 can be communicatively coupled to the memory device 102 through the micro-bumps 111, the external bumps 115, the direct access bumps 116, or a combination thereof.

In some embodiments, the direct access bumps 116 (e.g., one or more of the bumps 115) and/or other bumps may be organized into a probe pad (e.g., a set of test connectors). A tester 150 may be coupled onto the probe pad in order to directly communicate with the memory device 102. In other words, the tester 150 may send signals to and/or receive signals from the memory device 102, without the signals passing through the processor 110, after the memory device 102 is mounted on the interposer 112. Additionally or alternatively, the tester 150 may be used to test the memory device 102 before it is mounted on the interposer 112 and/or coupled to the processor 110.

In some embodiments, the tester 150 can function as a host device for the test that interacts with a test circuit (e.g., a BIST circuit) of the memory device 102 to implement the test. The tester 150 may be used to load one or more test patterns into a test pattern memory (e.g., predetermined registers) of the interface die 104. The tester 150 may then provide one or more test instructions along the direct access uBumps 116. The interface die 104 may perform one or more tests on the memory device 102 based on the test instructions and the loaded test patterns and may generate result information. The test results can be monitored during the test to find when failure occurs or read at the end of the test for a pass/fail conclusion.

The test patterns and the instructions can correspond to one or more tests performed on the memory device 102. The test may involve loading a pattern of data into one or more memory cells of the memory device 102 as part of a write operation, retrieving the stored information from the memory cells as part of a read operation, and comparing the written data to the read data. A test may be performed using the BIST circuit of the memory device 102. The tests may be performed using predetermined test patterns with random characteristics, which may require more storage space than is practical in the BIST circuit. Such tests may be performed by directly sending test patterns and instructions through the DA uBumps 116.

As described in detail below, the memory device 102 can include the test circuit and an interface manager that are configured to support testing of multiple memory types and the corresponding interfaces/protocols. For example, the memory device 102 can include the test circuit and the interface manager that can support self-tests of the core dies 106 (e.g., DRAM), the other non-targeted memory within the HBM, the off-chip memory 120, other memories external to the memory device 102, or a combination thereof.

### Example Test Circuits

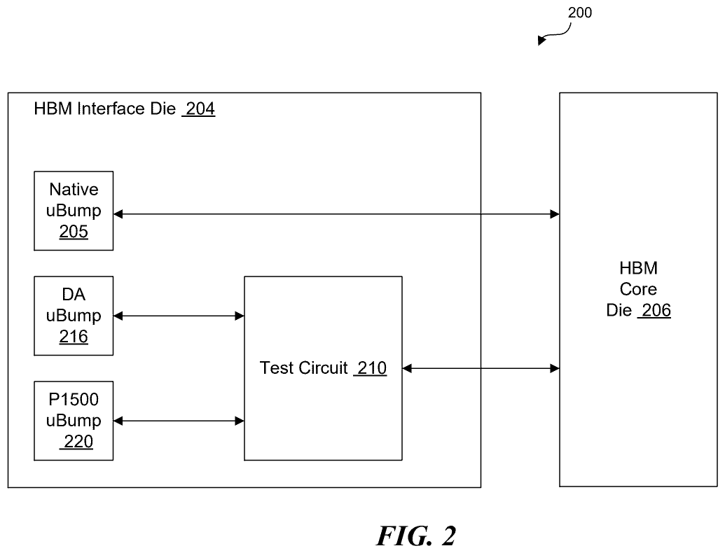

FIG. 2 is a schematic block diagram of a test circuit for a memory device 200. The memory device 200 can illustrate a conventional HBM memory having an interface die 204 and a set of core dies 206. The memory device 200 can include different interface terminals for coupling external circuitry to one or more circuits of the memory, including the core dies 206. The different interface terminals can include native micro-bumps (uBumps) 205, DA uBumps 216, and/or test interface uBumps 220. The test interface uBumps 220 may be part of a specific interface protocol, such as the IEEE 1500 interface (also referred to as a P1500 interface).

The native uBumps 205 may, in some embodiments, be included in the uBumps 111 of FIG. 1. The native uBumps 205 may be coupled to a processor (e.g., the processor 110 of FIG. 1) via one or more connections (e.g., the channels 105 of FIG. 1). The native uBumps 205 and the connections can enable the processor to access information (via, e.g., read or write operations and the corresponding exchange of information) in the core die(s) 206.

In addition to the operational configurations (e.g., native operational mode) associated with the native uBumps 205, the memory device 200 can be configured to operate in a test mode (e.g., a BIST mode or other self-test modes). In test mode, the memory device 200 can determine one or more characteristics (e.g., signal responses, manufacturing defects, failure or error related aspects, or other aspects of the circuit) of the memory device 200. The memory device 200 may utilize the P1500 uBumps 220 and/or the DA uBumps 216 as the test interface. For example, the P1500 uBumps 220 may be used to communicate signals with the host device according to a predetermined sequence or protocol for sending and receiving signals.

To implement such tests, the memory device 200 can include a test circuit 210 that is directly coupled to the P1500 uBumps 220 and/or the DA uBumps 216. In conventional memory devices, the test circuit 210 can be configured to test the main memory in the core dies 206. Hence, the testing features of conventional memory devices are focused on one memory type (e.g., DRAM) and one corresponding interface. As such, conventional memory devices fail to provide expanded/customizable testing capabilities.

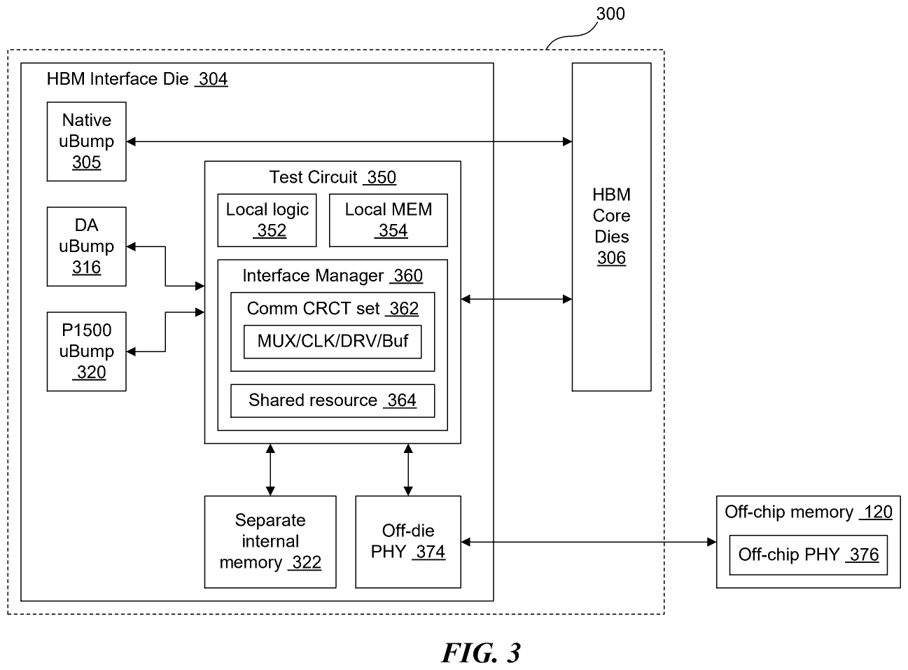

FIG. 3 is a schematic block diagram of a memory device 300 (e.g., an example of the memory device 102 of FIG. 1) including a test circuit 350 in accordance with an embodiment of the present technology. The memory device 300 can include an HBM memory device having an interface die 304 and a set of core dies 306. The memory device 300 can include different interface terminals for coupling external circuitry to one or more circuits of the memory, including the core dies 306. The different interface terminals can include native micro-bumps (uBumps) 305, DA uBumps 316, and/or test interface uBumps 320. The test interface uBumps 320 may be part of a specific interface protocol, such as the IEEE 1500 interface (also referred to as a P1500 interface).

The native uBumps 305 may, in some embodiments, be included in the uBumps 111 of FIG. 1. The native uBumps 305 may be coupled to a processor (e.g., the processor 110 of FIG. 1) via one or more connections (e.g., the channels 105 of FIG. 1). The native uBumps 305 and the connections can enable the processor to access information (via, e.g., read or write operations and the corresponding exchange of information) in the core die(s) 306. In other words, the native uBumps 305 can be used for operational configurations.

In addition to the operational configurations (e.g., native operational mode) associated with the native uBumps 305, the memory device 300 can be configured to operate in a test mode (e.g., a BIST mode or other self-test modes). In test mode, the memory device 300 can determine one or more characteristics (e.g., signal responses, manufacturing defects, failure or error related aspects, or other aspects of the circuit) of the memory device 300. The memory device 300 may utilize the P1500 uBumps 320 and/or the DA uBumps 316 as the test interface. For example, the P1500 uBumps 320 may be used to communicate signals with the host device according to a predetermined sequence or protocol for sending and receiving signals.

The P1500 uBumps 320 and/or the DA uBumps 316 can be directly coupled to the test circuit 350 that is configured to test or facilitate testing of multiple types of memory. For example, the test circuit 350 can communicate with the tester 150 of FIG. 1 through the P1500 uBumps 320 and/or the DA uBumps 316. The test circuit 350 can be configured to test separate internal memory 322 (e.g., SRAM, DRAM, and/or NAND separate from the targeted memory in the core dies 306) and/or the off-chip memory 120 in addition to the targeted memory cells in the core dies 306. Stated differently, the test circuit 350 can be configured to test non-targeted or two or more memories within the HBM stack and/or additionally test the off-chip memory 120. In being configured to test across the different memories, the test circuit 350 can be configured to test multiple types of memories, such as two or more of SRAM, DRAM, and/or NAND, multiple memories using different word sizes, different communication protocol (e.g., different speeds, voltages, currents, etc.), or a combination thereof.

In some embodiments, the memory device 300 can include a local logic 352 and/or a local memory 354. The local logic 352 and/or the local memory can be configured to provide internal functions of the memory device 300 including the self-test operations for testing the different types of circuits within the memory device 300 and/or the off-chip memory 120. The local logic 352 and the local memory 354 can be located in the interface die 304.

In addition, the test circuit 350 can include an interface manager 360 configured to support the communication/interfaces for testing the different types of memories (e.g., DRAM, SRAM, NAND, on-chip, off-chip, etc.). For example, the interface manager 360 can be configured to support communications or formats associated with P1500, JTAG, ONFI, single/differential connections, different termination settings, and/or the like. Essentially, the interface manager 360 can selectively support two or more communication settings that differ in physical connections, communication speeds, physical/electrical signal requirements, messaging formats/protocols, bandwidths, and/or the like. Accordingly, the interface manager 360 can selectively support testing of the core dies 306 (e.g., the target memory cells) in addition to the separate internal memory 322, the off-chip memory 120, or a combination thereof.

The interface manager 360 can include a set of communication circuits 362. Each set of circuits within the set 362 can include circuitry, such as a clock, a driver, a receiver, a set of buffers, or a combination thereof, unique for the corresponding interface. For example, the set of communication circuits 362 can include separate circuits for interfacing with DRAM, SRAM, one or the core dies 306, the off-chip memory 120, or a combination thereof.

The test circuit 350 can further include a selector, a multiplexor, or the like coupled to and configured to facilitate the selective communications across the set of communication circuits 362. The test circuit 350 can also include a shared resource 364, such as circuitry and/or data commonly used in testing across the various memory types. For example, the shared resource 364 can include a template test pattern or routine, a data comparison circuitry, or the like that can serve as the basis for testing the core dies 306 along with the various other on-chip and/or off-chip memories. The shared resource 364 can further include a physical layer (PHY) circuit configured to implement communications with an upstream device, such as the processor 110. The selector and the multiplexor can couple the selected interface circuitry from the set of communication circuits 362 to the share resource 364, to the DA uBump 316, to the P1500 uBump 320, or a combination thereof.

As an illustrative example, a user/customer/manufacturer for the memory device 300 can provide a setting, such as using a dip switch, a custom pin setting, or the like, to identify the different types of memory targeted for testing. The local logic 352 (e.g., executing the instructions stored in the local embedded memory 354) can determine the designated setting and the corresponding types of memory, such as to test the DRAMs and/or NANDs in the core dies 306 along with the separate internal memory 322, the off-chip memory 120, or a combination thereof. The local logic 352 can further select and activate the circuitry in the set 362 that corresponds to the designated setting. Moreover, the local logic 352 can utilize the shared resources appropriately for the designated setting, such as by adjusting the word lengths, adjusting the test pattern, or the like. The interface manager 360 can implement the physical signaling and interfacing for the designated setting. Accordingly, the mBIST function can be performed according to the customized use of the memory device 300 and support additional testing using the shared/common circuits (e.g., the DA uBump 316, the P1500 uBump 320, the test circuit 350, the shared resources 364, and/or the interface die 304).

In testing the off-chip memory 120, the test circuit 350 and the interface manager 360 can be coupled to an off-die physical layer (PHY) circuitry 374. The off-die PHY 374 can be connect to an off-chip PHY 376 within the off-chip memory 120. Accordingly, the off-die PHY 374 and the off-chip PHY 376 can be used to exchange the signals used to test the off-chip memory 120. In other words, the test circuit 350 in the memory device 300 can be used to implement the self-test of the off-chip memory 120.

### Control Flow

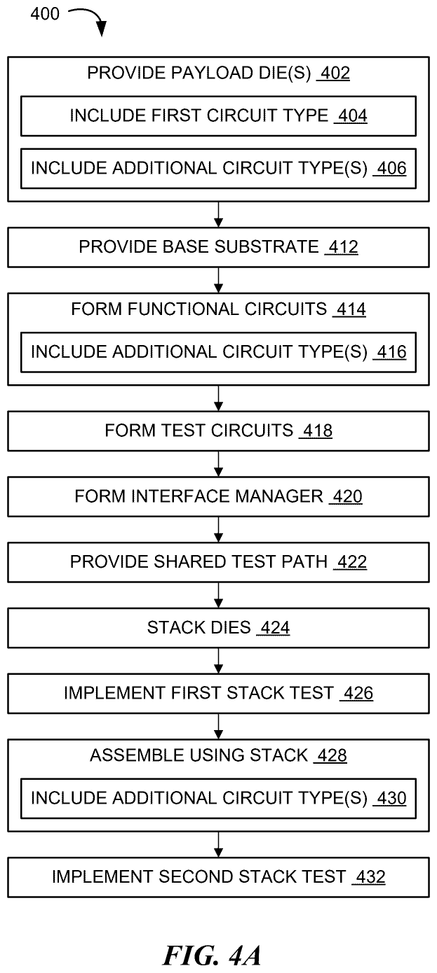

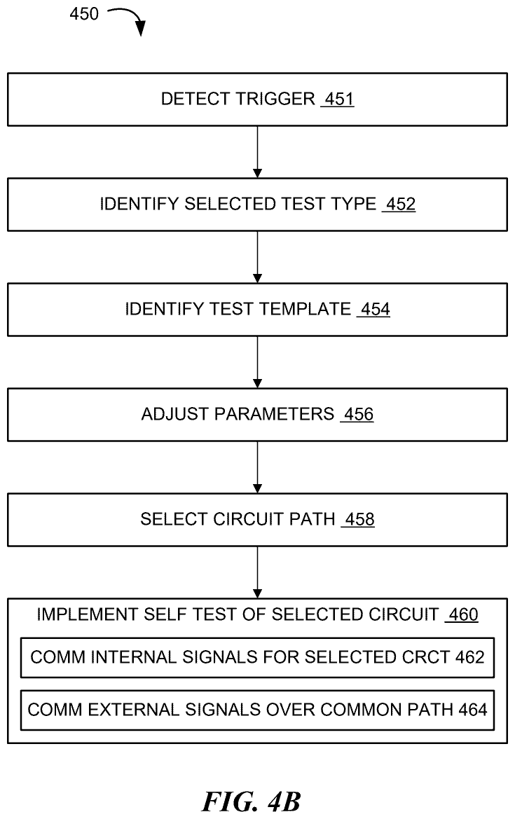

FIG. 4A is a flow diagram illustrating an example method 400 of manufacturing an apparatus (e.g., the SiP 100 of FIG. 1, the memory device 300 of FIG. 3, etc.) in accordance with an embodiment of the present technology. The method 400 can be for manufacturing the test circuit 350 of FIG. 3, the interface manager 360 of FIG. 3, or a combination thereof and the corresponding die, stack device, assembly, package, etc.

At block 402, the method 400 can include providing payload die(s). Payload die(s), such as the core dies 106 of FIG. 1 and/or the core dies 306 of FIG. 3 can include at least a first circuit type as shown at block 404. In some embodiments, the payload dies can further include a second circuit type as shown at block 406. Providing the payload dies can include obtaining the dies, preparing the dies for subsequent manufacturing steps, and/or manufacturing the dies (e.g., implanting and forming storage circuits on semiconductor dies).

As an illustrative example, the payload dies can include one or more DRAM dies that include DRAM storage circuits (an example of the first circuit type). The payload dies can further include a second circuit type, such as SRAM, read-only memory, registers, or the like local to the DRAM dies. Further the payload dies can further include persistent memory dies, such as NAND dies, in addition to the DRAM dies.

At block 412, the method 400 can include providing a base substrate, such as a semiconductor substrate, for manufacturing the interface die 104 of FIG. 1 and/or the interface die 304 of FIG. 1. In some embodiments, the base substrate can include a semiconductor wafer positioned for forming circuitry.

At block 414, the method 400 can include forming functional circuits on the base substrate. The functional circuits can include circuitry configured to implement the operational or post-deployment functions of the interface die. For example, the functional circuits can include the local logic 352 of FIG. 3 and/or the local memory 354 of FIG. 3 used for general operation. Also, the function circuits can include other circuits be configured to facilitate access, such as for reading, writing, and/or performing other memory operations, to the core dies for the upstream processor (e.g., the processor 110 of FIG. 1). The functional circuits can include PHY circuits for the upstream communication and/or PHY circuits (e.g., the off-die PHY 374 of FIG. 3) for the downstream communication to/from other off-chip or off-package device, such as the off-chip memory 120 of FIG. 3.

As illustrated at block 416, the formed functional circuits can correspond to additional circuit type(s) different from the first circuit type. For example, the functional circuits formed on the base substrate and within the interface die can include the separate internal memory 322 of FIG. 3, such as SRAM, DRAM, NAND, registers, and/or the like, different from and/or in addition to the provided payload/core dies (e.g., DRAM).

At block 418, the method 400 can include forming test circuits, such as the test circuit 350 of FIG. 3, configured to implement and/or facilitate a self-test of the targeted device (e.g., the memory device 102, the off-chip memory 120, etc.). For example, mBIST circuit can be formed on the base substrate. The formed test circuits can be configured to write predetermined data pattern, read back written data, compare the read-back data to the predetermined data pattern, and generate corresponding results. The test circuit can be configured to test one type of circuit/memory and/or no particular type of circuit/memory.

At block 420, the method 400 can include forming an interface manager, such as the interface manager 360 of FIG. 3, configured to adapt the self-test to test multiple circuit types. For example, multiple circuit paths can be formed that are each configured for implementing the self-test for one circuit type. The circuit paths can be coupled to a multiplexor or a selector coupled to the test circuit 350 and the shared resource 364 of FIG. 3.

At block 422, the method 400 can include providing a shared test path, such as for using the same external connections to facilitate self-test of multiple circuit types. For example, the interface manager can be communicatively coupled to the shared ports or other external interface component, such as the DA pads, P1500 pads, or the like for the corresponding uBumps. The direct connection and the corresponding DA uBumps and/or the P1500 uBumps can be used to communicate with the external tester(s) in self-testing the multiple circuit types.

At block 424, the method 400 can include stacking the dies. For example, the wafer corresponding to the base substrate can be finalized and singulated to form the interface dies. The dies provided in block 402 can be stacked on top of the interface die to form the memory device 102/300 (e.g., the HBM device). As described above, the stacked device can include two or more types of circuits/memories.

At block 426, the method 400 can include implementing a first stack test. For example, the memory device 102 can implement a self-test for the first circuit type and/or the additional circuit types included in the interface die, the core dies, or both. Details regarding the self-test are described above and further below.

At block 428, the method 400 can include assembling a package, such as the SiP 100 of FIG. 1, using the stack device. For example, the memory device 102/300 can be mounted on the interposer 112 of FIG. 1 along with the processor 110. The interposer can be attached to the package substrate 114 of FIG. 1.

The assembled package can include additional circuit types as shown in block 430. For example, in assembling, the off-chip memory 120 can be communicatively coupled to the interface die 104/304. Accordingly, the SiP 100 can have the memory device 102 coupled to the upstream processor 110 along with the off-chip memory 120 downstream. The interface die 104/304 can facilitate communications to/from the off-chip memory 120, such as for providing corresponding access for the upstream processor 110 and/or for self-testing the off-chip memory 120.

At block 432, the method 400 can include implementing a second stack test. For example, the memory device 102 can implement a self-test for the first circuit type and/or the additional circuit types included in the interface die, the core dies, the off-chip memory 120, or a combination thereof. Details regarding the self-test are described above and further below.

The formed circuits, such as functional circuits, the test circuits, and the interface manager, can be formed by implanting dopants, masking to outline patterns, etching to form patterned structures, depositing metal for signal routing, and/or other semiconductor manufacturing techniques. Similarly, the die stacking and package assembly can utilize corresponding manufacturing techniques, such as mounting, reflow, cooling, bonding, and the like.

FIG. 4B is a flow diagram illustrating an example method 450 of operating an apparatus (e.g., the SiP 100 of FIG. 1, the memory device 300 of FIG. 3, etc.) in accordance with an embodiment of the present technology. The method 450 can be for operating the test circuit 350 of FIG. 3, the interface manager 360 of FIG. 3, or a combination thereof. The method 450 can be for operating the apparatus 100 to test two or more types of memories within a corresponding die, stack device, assembly, package, etc. The method 450 can be used for the first and second stack tests of blocks 426 and 432 of FIG. 4A.

At block 451, a trigger for the self-test can be detected. For example, an external tester can be coupled (e.g., directly for block 426 or through the substrate 114 and the interposer 112 of FIG. 1 for block 432) to the memory device 102 of FIG. 1 and the interface die 104/304 therein. The external tester and/or the connection can provide a trigger condition, such as a corresponding circuit path/resistance change, a trigger, signal, or the like. The test circuit 350 of FIG. 3 and/or the local logic 352 of FIG. 3 can detect the provided trigger condition.

At block 452, the test circuit 350 and/or the local logic 352 can identify a selected test type. In some embodiments, the external tester can provide a signal that identifies one of the circuit/memory types within or coupled to the memory device 102. In other embodiments, the test circuit 350 and/or the local logic 352 can identify the included or coupled memory types, such as by accessing a manufacturing setting (e.g., a dip switch, a pin setting, a permanently stored data, or the like). The test circuit 350 and/or the local logic 352 can iteratively test the included/coupled memory according to a predetermined sequence. In identifying the selected test type, the test circuit 350 and/or the local logic 352 can identify the iteration count or the progress within the predetermined sequence and the corresponding memory type.

At block 454, the test circuit 350 and/or the local logic 352 can identify a test template. For example, the test circuit 350 and/or the local logic 352 can access a predetermined data pattern, a test sequence (e.g., a sequence of instructions), a set of addresses, or a combination thereof. The test circuit 350 and/or the local logic 352 can include predetermined instances of the data pattern, the test sequence, and/or the addresses for implementing self-tests for multiple circuit types. The predetermined information can provide a test for one of the self-tests and/or a starting point for each of the multiple self-tests.

At block 456, the test circuit 350 and/or the local logic 352 can adjust one or more parameters for the test template according to the selected test type. For example, the test circuit 350 and/or the local logic 352 can adjust a word length, a number of write locations, a timing parameter, a write sequence, an instruction sequence, a clock speed, a buffer size, or a combination thereof of the test template associated according to the selected test type. The test circuit 350 and/or the local logic 352 can adjust the parameters according to predetermined equations, instructions, or the like.

At block 458, the test circuit 350 and/or the local logic 352 can select a circuit path. For example, the test circuit 350 and/or the local logic 352 can generate a signal for selecting a circuit path that corresponds to the selected test type. In response, the interface manager 360 can operate one or more switches or multiplexors to connect the selected circuit path to the shared resource 364, the eternal interfaces (the DA uBumps 316, the P1500 uBumps 320), and/or the off-die PHY 374.

At block 460, the test circuit 350 and/or the local logic 352 can implement the self-test according to the adjusted parameters, the selected circuit path, and the test template. For example, the test circuit 350 and/or the local logic 352 can write the adjusted test pattern and/or the adjusted words to the selected locations/addresses and then read back from the same location. Thus, the test circuit 350 and the interface manager 360 can communicate internal signals, such as the writes and reads, for selected circuits (e.g., via the selected addresses), as shown at block 462. In some embodiments, the test circuit 350 and/or the local logic 352 can implement the self-test of the off-chip memory via communications downstream or internal to the memory portion of the computing device.

The test circuit 350 and/or the local logic 352 can compare the readback data to the adjusted test pattern/words to generate a result of the implemented self-test. At block 464, the test circuit 350 and/or the local logic 352 can send the test result through the shared interface, such as the DA uBump 316 and/or the P1500 uBump 320, to the external tester. Regardless of the selected circuit type or for all selectable circuit types, the test circuit 350 and/or the local logic 352 can communicate the test result through the shared interface.

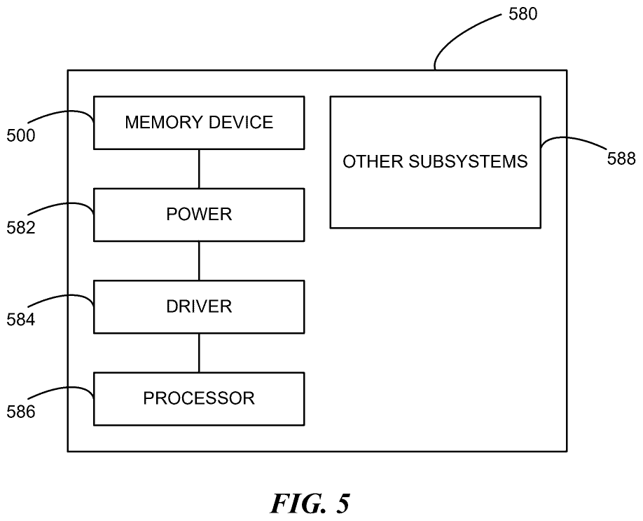

FIG. 5 is a schematic view of a system that includes an apparatus in accordance with embodiments of the present technology. Any one of the foregoing apparatuses (e.g., memory devices) described above with reference to FIGS. 1, 3, 4A, and 4B can be incorporated into any of a myriad of larger and/or more complex systems, a representative example of which is system 580 shown schematically in FIG. 5. The system 580 can include a memory device 500, a power source 582, a driver 584, a processor 586, and/or other subsystems or components 588. The memory device 500 can include features generally similar to those of the apparatus described above with reference to FIGS. 1, 3, 4A, and 4B, and can therefore include various features for performing a direct read request from a host device. The resulting system 580 can perform any of a wide variety of functions, such as memory storage, data processing, and/or other suitable functions. Accordingly, representative systems 580 can include, without limitation, hand-held devices (e.g., mobile phones, tablets, digital readers, and digital audio players), computers, vehicles, appliances and other products. Components of the system 580 may be housed in a single unit or distributed over multiple, interconnected units (e.g., through a communications network). The components of the system 580 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1, 3, 4A, 4B, and 5.

I/We claim:

1. A semiconductor memory device, comprising:
at least one core memory die including target memory cells configured to store data and provide access to stored data for a host device, wherein the target memory cells correspond to a first memory type;
an interface die having the at least one core memory die stacked thereon and configured to:
facilitate communications with the host device, and
facilitate a self-test of the target memory cells,
wherein the interface die includes an interface manager configured to adapt communications for the self-test to test a second memory type different than the first memory type.

2. The semiconductor memory device of claim 1, wherein:
semiconductor memory device is a high-bandwidth memory (HBM) device;
the first memory type is a Dynamic Random-Access Memory (DRAM); and
the interface manager includes circuitry configured to facilitate the self-test for the DRAM target memory cells in addition to the second memory type.

3. The semiconductor memory device of claim 2, wherein:
the interface die includes a second storage circuit of the second memory type; and
the interface manager includes the circuitry configured to adapt a word length, a speed, a bandwidth, a sequence, a protocol, or a combination thereof for implementing the self-test across the first and second memory types.

4. The semiconductor memory device of claim 2, wherein:
the at least one core memory die further includes second memory cells of the second memory type; and
the interface manager includes the circuitry configured to adapt a word length, a speed, a bandwidth, a sequence, a protocol, or a combination thereof for implementing the self-test across the first and second memory types.

5. The semiconductor memory device of claim 4, wherein the at least one core memory die includes:
one or more first type of dies having DRAM memory cells; and
one or more second type of dies stacked together with the one or more first type of dies, the one or more second type of dies having memory cells of the second memory type.

6. The semiconductor memory device of claim 2, wherein the interface manager includes the circuitry configured to adapt a word length, a speed, a bandwidth, a sequence, a protocol, or a combination thereof for implementing the self-test of off-chip memory communicatively coupled to the HBM and connected downstream relative to the host device.

7. The semiconductor memory device of claim 6, wherein the interface die further includes:
a first set of physical layer circuits configured to facilitate the communications with the host device; and
a second set of physical layer circuits coupled to the interface manager and configured to facilitate the communications with the off-chip memory.

8. The semiconductor memory device of claim 2, wherein the second type of memory includes an off-chip memory, a persistent memory, a Static Random Access Memory (SRAM), or a combination thereof.

9. The semiconductor memory device of claim 1, wherein the interface die further includes a communication port configured to provide a communication interface with one or more testers external to the semiconductor memory device, wherein the communication port is configured to provide the communication interface for the self-test for the first type of memory and the second type of memory.

10. The semiconductor memory device of claim 9, wherein the interface die further includes a self-test circuit configured to:
identify a selected memory and a corresponding memory address, wherein the selected memory represents the first memory type or the second memory type;
adapt a test pattern according to the selected memory, wherein the test pattern represents a predetermined pattern of data;
operate the interface manager to select a circuit path according to the selected memory;
write the test pattern to the memory address using the selected circuit path;
read a readback data from the memory address using the selected circuit path; and
determine a self-test result based on comparing the readback data to the test pattern.

11. A method of operating a semiconductor memory device, the method comprising:
identifying a selected memory that represents a selection from two or more memory types, wherein the semiconductor memory device includes and/or is communicatively coupled to the two or more memory types that have different operating protocols;
determining a memory location that corresponds to the selected memory;
generating a test result from implementing a self-test for the memory location according to an operating protocol of the selected memory, wherein the self-test is implemented using a common resource shared in testing the two or more memory types; and
providing the test result to an external device using a common interface shared for reporting self-test results of the two or more memory types.

12. The method of claim 11, wherein the semiconductor memory device includes a High Bandwidth Memory (HBM) device having at least one core memory die stacked on an interface die, the interface die including (1) a test circuit configured to implement the self-test and (2) an interface manager configured to adjust the self-test according to the selected memory, wherein the interface manager includes the shared common resource.

13. The method of claim 12, further comprising:
adapting a test pattern according to the selected memory, wherein the test pattern represents a predetermined pattern of data;
operating the interface manager to select a circuit path according to the selected memory;
wherein generating the test result includes:
writing the adapted test pattern to a memory address using the selected circuit path;
reading a readback data from the memory address using the selected circuit path; and
determining the test result based on comparing the readback data to the test pattern.

14. The method of claim 13, wherein:
the two or more memory types include two or more of Dynamic Random-Access Memory (DRAM), Static Random-Access Memory (SRAM), and NAND memory located within the HBM;
adapting the test pattern includes adjusting one or more parameters of the test pattern, wherein the one or more parameters include a word-size, a write sequence, a number of writes, or a combination thereof; and
operating the interface manager to select the circuit path includes selecting a protocol associated with the selected memory, wherein the protocol controls a communication speed, a buffer size, a physical signal characteristic, or a combination thereof.

15. The method of claim 13, wherein:
the two or more memory types include (1) an on-device memory located within the HBM and an off-device memory separate from and communicatively coupled to the HBM;
operating the interface manager to select the circuit path includes selecting a memory access path between (1) an internal access path associated with the on-device memory and (2) a physical layer circuit configured to communicatively couple the HBM to the off-device memory; and
providing the test result includes providing a result of testing the off-device memory through the common interface in the HBM.

16. A semiconductor interface die, comprising:
a self-test circuit configured to perform a self-test of circuits;
an interface manager coupled to the self-test circuit and configured to adapt communications for the self-test to implement at least a first test for a first circuit type and a second test for a second circuit type; and
an external communication pad coupled to the interface manager and configured to facilitate communications with one or more external devices for the first and second tests.

17. The semiconductor interface die of claim 16, wherein:
the semiconductor interface die is configured to be stacked with one or more dies that have the first circuit type therein; and
the second test is for testing the second circuit type located on the semiconductor interface die.

18. The semiconductor interface die of claim 16, wherein the semiconductor interface die is configured to be stacked with a first die having circuits of the first circuit type and a second die having circuits of the second circuit type.

19. The semiconductor interface die of claim 16, wherein the semiconductor interface die is configured to:
communicate with circuits of the first circuit type within one or more dies that are mounted on the semiconductor interface die;
provide access to the circuits of the first circuit type for an upstream host device;
the second test is for testing the second circuit type located external and downstream to the semiconductor interface die.

20. The semiconductor interface die of claim 16, wherein the first and second circuit types include different ones or combinations of Dynamic Random-Access Memory (DRAM), Static Random-Access Memory (SRAM), registers, persistent memory, read only memory, rewritable memory, on-chip memory, off-chip memory, stack-internal memory, and stack-external memory.
